(19) United States
(12) Patent Application Publication
(10) Pub. No.: US 2010/0190337 A1
(43) Pub. Date: Jul. 29, 2010

(54) Method of Forming Metal Wirings of Semiconductor Device

(75) Inventor: Chang Jin Lee, Cheongju-si (KR)

Correspondence Address: MARSHALL, GERSTEIN & BORUN LLP, 233 SOUTH WACKER DRIVE, 6300 WILLIS TOWER, CHICAGO, IL, 60606-6357, US

(73) Assignee: HYNIX SEMICONDUCTOR INC., Icheon-si (KR)

(21) Appl. No.: 12/650,490

(22) Filed: Dec. 30, 2009

(30) Foreign Application Priority Data
Jan. 29, 2009 (KR) 10-2009-0006804

(51) Int. Cl. H01L 21/768

(52) U.S. Cl. 438/666; 257/E21.585

(57) ABSTRACT

A method of forming metal wirings of a semiconductor device includes providing a semiconductor substrate having a number of underlying conductive patterns separated from each other with a first insulating layer interposed between the underlying conductive patterns. The method also includes forming auxiliary patterns over the underlying conductive patterns, respectively, forming a second insulating layer over the first insulating layer to fill a space between the auxiliary patterns, removing the auxiliary patterns to form damascene patterns through which the underlying conductive patterns are respectively exposed, and filling interiors of the damascene patterns with a metal material.

### CROSS-REFERENCE TO RELATED APPLICATION

Priority to Korean patent application number 10-2009-0006804 filed on Jan. 29, 2009, the entire disclosure of which is incorporated by reference herein, is claimed.

### BACKGROUND

1. Field of the Invention

The disclosure relates to a method of forming metal wirings of a semiconductor device and, more particularly, to a method of forming metal wirings such that the capacitance between the wirings is reduced.

2. Brief Description of Related Technology

Recently, active research has been directed to developing NAND flash memory devices having a high degree of integration.

The NAND flash memory device includes a memory cell array and page buffers. The memory cell array includes a number of cell strings each having a number of memory cells coupled together in series, a source select transistor coupled to one end of each of the cell strings, and a drain select transistor coupled to the other end of each of the cell strings. The memory cells of the cell strings arranged in parallel are coupled together via word lines. Here, the drain select transistor selectively couples a corresponding cell string and a bit line. Furthermore, the source select transistor selectively couples a corresponding cell string and a global source line coupled to the ground.

Each of the page buffers writes data into specific cells of the memory cell array or reads data stored in a specific cell. To read data stored in a memory cell, a corresponding bit line is precharged to a first voltage, a second voltage less than the first voltage is supplied to the bit line, and a shift in the voltage level of the bit line is sensed. At this time, a process of storing a detected shift in the voltage level of the bit line in a latch circuit of the corresponding page buffer is performed. Here, the time taken for the voltage level of the bit line to shift to the extent that data stored in the latch circuit can be changed is called a sensing time. In a NAND flash memory device, most of the time taken to perform a read operation is the sensing time. Thus, to improve the speed of a NAND flash memory device, the sensing time needs to be reduced. The sensing time is expressed by the following equation.

Sensing Time=C_{BL}·ΔV/Icell

where C_{BL} is the capacitance between bit lines, ΔV is a difference between a first voltage and a second voltage, and Icell is current flowing through a cell string.

From the above equation, it can be seen that the sensing time is influenced by the capacitance between bit lines (C_{BL}).

Meanwhile, with the high degree of integration of semiconductor devices, the size of a NAND flash memory device is reduced, and so the interval between the bit lines is narrowed. In this case, a problem arises because the sensing time is increased resulting from an increase in the capacitance between bit lines (C_{BL}). Accordingly, there is a need for a NAND flash memory device in which the capacitance between bit lines (C_{BL}) is not increased, although the interval between the bit lines is narrowed.

The problem in an increase in the capacitance between wirings, caused by a narrowed gap between the wirings with the high degree of integration of semiconductor devices, can be problematic in not only bit lines, but also various metal wirings of a semiconductor device arranged on the same line.

A method of forming metal wirings as well as bit lines is described in detail below. To form the metal wirings, a semiconductor substrate in which underlying conductive patterns, including the gate patterns of the semiconductor device, and a first insulating layer are formed is first provided. The first insulating layer is formed to insulate the underlying conductive patterns from each other and is formed of an oxide layer. A second insulating layer, having a stack structure of a nitride layer and an oxide layer, is formed over the first insulating layer. The second insulating layer is etched to form damascene patterns in the second insulating layer, and the metal wirings are formed within the damascene patterns. Accordingly, the metal wirings are insulated from each other through the second insulating layer having the stack structure of the nitride layer and the oxide layer. Here, because the nitride layer is etched more slowly than the oxide layer, the nitride layer serves as an etch-stop layer for preventing the first insulating layer, formed of the oxide layer, from being over etched in the process of forming the damascene patterns in the second insulating layer. However, the nitride layer has a higher dielectric constant than the oxide layer, and so increases the capacitance between the metal wirings.

### SUMMARY OF THE INVENTION

Disclosed herein are embodiments of a method of forming the metal wirings of a semiconductor device, which method is capable of reducing the capacitance between the wirings.

The method generally includes providing a semiconductor substrate having a number of underlying conductive patterns separated from each other with a first insulating layer interposed between the underlying conductive patterns. The method also includes forming auxiliary patterns over the underlying conductive patterns, respectively. Furthermore, the method includes forming a second insulating layer over the first insulating layer to fill a space between the auxiliary patterns. Still further, the method includes removing the auxiliary patterns to form damascene patterns through which the underlying conductive patterns are respectively exposed, and filling interiors of the damascene patterns with a metal material.

The formation of the auxiliary patterns can include forming an auxiliary layer over the first insulating layer and the underlying conductive patterns, and etching the auxiliary layer to expose the first insulating layer to form the auxiliary patterns.

The auxiliary layer can be etched using a dry etch process. This etching can be carried out with a material having a faster etch rate than a material used to etch the first insulating layer.

Forming auxiliary patterns can include forming an auxiliary layer over the first insulating layer and the underlying conductive patterns, and etching the auxiliary layer (using, for example the dry etch process) to expose the first insulating layer to form the auxiliary patterns.

Preferably, each of the first and second insulating layers includes an oxide layer, and the auxiliary patterns include a silicon nitride (Si₃N₄) layer or a polysilicon layer.

Removing the auxiliary patterns can include removing the silicon nitride (Si₃N₄) layer through a wet etch process using H₃PO₄, and removing the polysilicon layer using an etchant that includes a mixture of HF, HNO₃, and acetic acid (HAc).

The second insulating layer can include air gaps.

The method further can include, before forming the auxiliary patterns, forming a buffer oxide layer over the underlying conductive patterns and the first insulating layer.

Removing the auxiliary patterns can include removing the buffer oxide layer formed over the underlying conductive patterns after removing the auxiliary patterns.

Additional features of the disclosed invention may become apparent to those skilled in the art from a review of the following detailed description, taken in conjunction with the drawings, and the appended claims.

### BRIEF DESCRIPTION OF THE DRAWINGS

For a more complete understanding of the disclosure, reference should be made to the following detailed description and accompanying drawings wherein:

FIGS. 1A to 1G are cross-sectional views illustrating a method of forming the metal wirings of a semiconductor device according to an embodiment of the present disclosure;

FIGS. 2A and 2B are cross-sectional views illustrating a method of forming the metal wirings of a semiconductor device according to another embodiment of the present disclosure; and,

FIGS. 3A and 3B are cross-sectional views illustrating a method of forming the metal wirings of a semiconductor device according to a yet another embodiment of the present disclosure.

While the disclosed methods are susceptible of embodiments in various forms, there are illustrated in the drawings (and will hereafter be described) specific embodiments, with the understanding that the disclosure is intended to be illustrative, and is not intended to limit the invention to the specific embodiments described and illustrated herein

### DETAILED DESCRIPTION

Hereinafter, some embodiments of the present disclosure will be described in detail with reference to the accompanying drawings. The figures are provided to allow those having ordinary skill in the art to understand the scope of the embodiments of the disclosure.

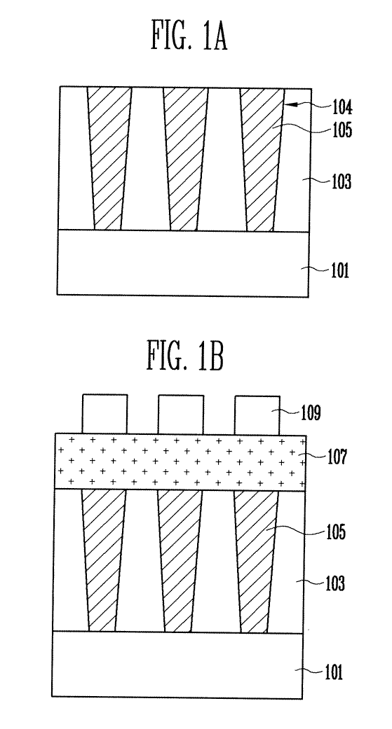

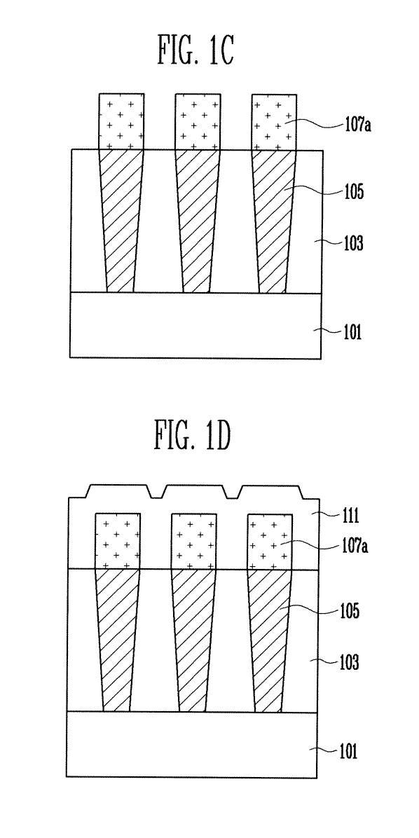

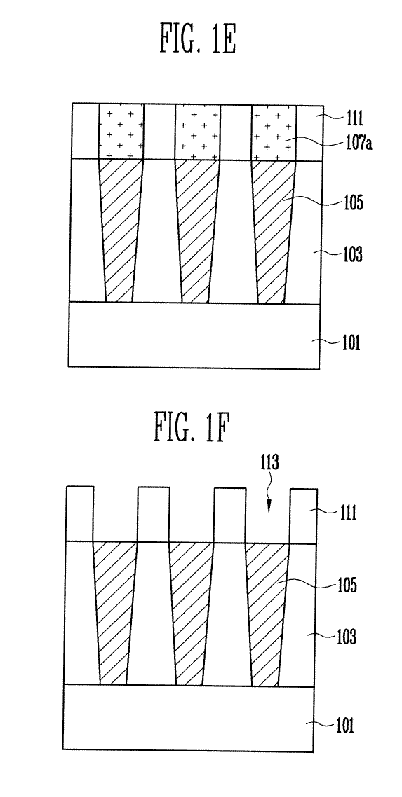

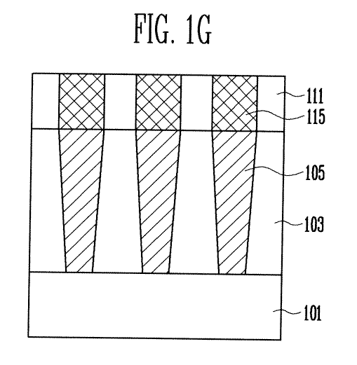

FIGS. 1A to 1G are cross-sectional views illustrating a method of forming the metal wirings of a semiconductor device according to a first embodiment of the present disclosure.

Referring to FIG. 1A, there is provided a semiconductor substrate 101 in which underlying conductive patterns 105 and a first insulating layer 103, insulating the underlying conductive patterns 105 from each other, are formed. The first insulating layer 103 is formed of an oxide layer, such as a silicon oxide (SiO₂) layer.

The underlying conductive patterns 105 can be formed by forming the first insulating layer 103 over the semiconductor substrate 101 and then etching the first insulating layer 103 to form first damascene patterns 104 including contact holes or trenches. Although not shown, the gate patterns of the semiconductor device can be further formed between the first insulating layer 103 and the semiconductor substrate 101, and junctions can be formed in the semiconductor substrate 101 on both sides of each gate pattern. In a NAND flash memory device, the underlying conductive pattern 105 can be a drain contact plug coupled to a drain region, from among the junctions.

Referring to FIG. 1B, an auxiliary layer 107 and first etch barrier patterns 109 are formed over the underlying conductive patterns 105 and the first insulating layers 103.

Each of the first etch barrier patterns 109 can have a stack structure of a hard mask layer and a photoresist layer or a single layer of a photoresist layer. The first etch barrier pattern 109 serves as a pattern defining a region in which an auxiliary pattern will be formed in a subsequent process.

The auxiliary layer 107 preferably is made of material that reacts to different chemical material from material forming the first insulating layer 103. The auxiliary layer 107 preferably is made of material having a fast dry etch rate as compared with the first insulating layer 103. In more detail, with consideration taken of the first insulating layer 103 formed of the oxide layer, the auxiliary layer 107 preferably is formed of a silicon nitride (Si₃N₄) layer reacting to H₃PO₄ or a polysilicon layer reacting to a mixture of HF, HNO₃, and acetic acid (HAc).

Referring to FIG. 1C, the auxiliary layer is etched to expose the first insulating layer 103 preferably using a dry etch process. Here, the auxiliary layer under the first etch barrier patterns is not etched, thus becoming auxiliary patterns 107a. After forming the auxiliary patterns 107a, the first etch barrier patterns are removed.

As described above, the first insulating layer 103 can be formed of the oxide layer, and the auxiliary layer 107 can be formed of a silicon nitride (Si₃N₄) layer or a polysilicon layer having a fast dry etch rate as compared with the oxide layer, i.e., having a faster dry etch rate than a material (etchant) used to etch the first insulating layer. Accordingly, when the dry etch process of forming the auxiliary patterns 107a is performed, the amount of the first insulating layer 103 that is lost can be controlled within a range of 100 Å.

The auxiliary patterns 107a serve as patterns to define regions in which second damascene patterns will be formed in a subsequent process. Meanwhile, in the subsequent process, metal wirings coupled to the underlying conductive patterns 105 have to be formed within the second damascene patterns. Thus, the auxiliary patterns 107a preferably are formed over the underlying conductive patterns 105.

Referring to FIG. 1D, a second insulating layer 111 is formed to a thickness sufficient to fill the space between the auxiliary patterns 107a. The second insulating layer 111 functions to insulate the metal wirings from each other, which will be formed in the subsequent process. Accordingly, to improve the capacitance between the metal wirings, the second insulating layer 111 preferably is formed of an oxide layer, such as a silicon oxide (SiO₂) layer, having a lower dielectric constant than a nitride layer.

The second insulating layer 111 can be deposited using a low pressure-chemical vapor deposition (LPCVD), plasma-enhanced CVD (PECVD), high density plasma (HDP), or spin-on dielectric (SOD) method. Here, in the case in which the second insulating layer 111 is deposited using an SOD method, a curing process can be further performed after the second insulating layer 111 is deposited.

Referring to FIG. 1E, a polishing process and an etch-back process are performed to remove the second insulating layer 111 on the top surface of the auxiliary patterns 107a. Consequently, the second insulating layers 111 are each formed to fill the space between the auxiliary patterns 107a and are spaced apart from each other with each auxiliary pattern 107a interposed therebetween. Furthermore, the auxiliary patterns 107a are exposed.

The above-described polishing process can be performed using a chemical mechanical polishing (CMP) method.

Referring to FIG. 1F, the exposed auxiliary patterns are removed, thereby forming second damascene patterns 113 through which the underlying conductive patterns 105 are exposed between the second insulating layers 111. The exposed auxiliary patterns can be removed using a wet etch process. As described above, because the auxiliary patterns are made of a different material from the first insulating layers 103, the loss of the first insulating layer 103 in the wet etch process for removing the auxiliary patterns can be prevented.

In the case in which the auxiliary patterns are formed of the silicon nitride (Si₃N₄) layer, they can be removed through a wet etch process using H₃PO₄. Furthermore, in the case in which the auxiliary patterns are formed of the polysilicon layer, they can be removed through a wet etch process using an etchant that includes a mixture of HF, HNO₃, and acetic acid (HAc).

Referring to FIG. 1G, the insides of the second damascene patterns, each formed between the second insulating layers 111, are filled with metal material, thereby forming metal wirings 115 respectively coupled to the underlying conductive patterns 105. The metal wirings 115 can be formed by forming the metal material on the entire surface of the second insulating layers 111, including the second damascene patterns, to a thickness sufficient to fill the second damascene patterns and then removing the metal material on the top surface of the second insulating layers 111 using a polishing process or an etch-back process. In the case in which the underlying conductive pattern 105 is a drain contact plug, the metal wiring 115 becomes a bit line.

As described above, in the first embodiment of the present disclosure, the auxiliary patterns can be formed over the underlying conductive patterns using material which has a fast dry etch rate as compared with oxide, and can be etched using a different etchant than that used to etch the oxide, filling the space between the auxiliary patterns with the second insulating layer, and then removing the auxiliary patterns to thereby form the second damascene patterns. That is, in the first embodiment of the present disclosure, a process of etching the second insulating layer needs not to be performed in order to form the second damascene patterns. Accordingly, in the first embodiment of the present disclosure, although the second insulating layer is formed of only an oxide layer, the first insulating layer is not over etched. Consequently, in the first embodiment of this disclosure, both the stability of the process and the capacitance between metal wirings can be improved because the over-etch problem of the first insulating layer is prevented although the second insulating layer is not formed of a nitride layer.

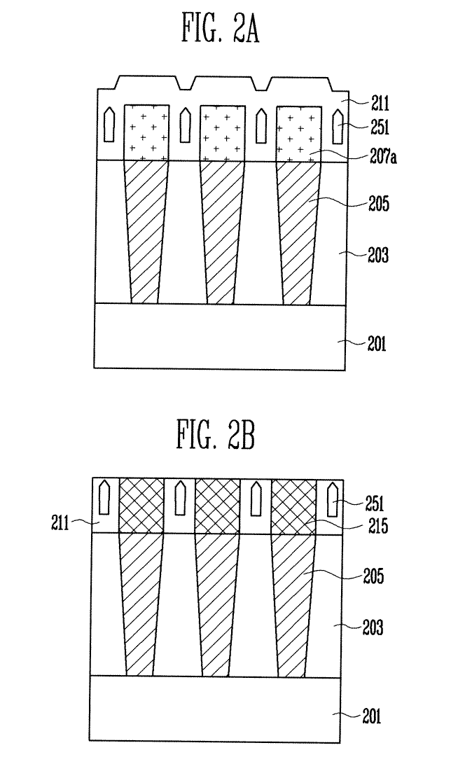

FIGS. 2A and 2B are cross-sectional views illustrating a method of forming the metal wirings of a semiconductor device according to a second embodiment of the present disclosure.

Referring to FIGS. 2A and 2B, the method of forming the metal wirings of a semiconductor device according to the second embodiment of the present disclosure is identical with the method according to the first embodiment of the present disclosure except that air gaps 251 are formed within a second insulating layer 211. Accordingly, a redundant description is omitted. As shown in FIG. 2A, each of the air gaps 251 formed within the second insulating layer 211 in a process of forming the second insulating layer 211 finally remains between metal wirings 215 as shown in FIG. 2B. The air gap 251 has a lower dielectric constant than an oxide layer, and so remains within the second insulating layer 211 formed between the metal wirings 215. Accordingly, the capacitance between the metal wirings 215 can be further lowered. In FIGS. 2A and 2B, reference numeral 201 identifies the semiconductor substrate, reference numeral 203 identifies the first insulating layer, reference numeral 205 identifies the underlying conductive patterns, and reference numeral 207a identifies the auxiliary patterns.

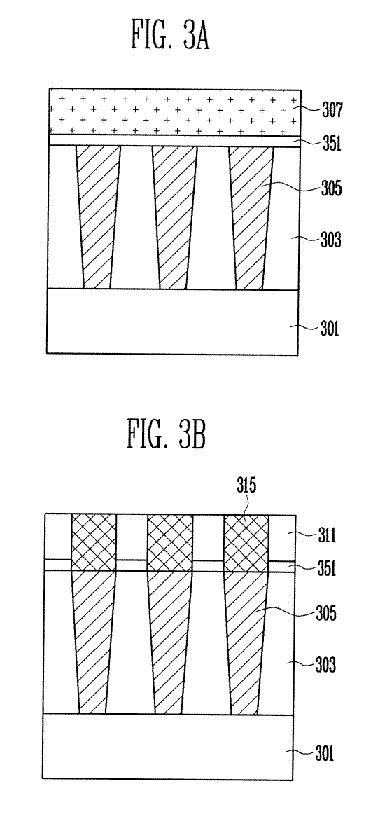

FIGS. 3A and 3B are cross-sectional views illustrating a method of forming the metal wirings of a semiconductor device according to a third embodiment of the present disclosure.

Referring to FIGS. 3A and 3B, the method of forming the metal wirings of a semiconductor device according to the third embodiment of the present disclosure is identical with the method according to the first embodiment of the present disclosure except that a buffer oxide layer 351 is further formed over a first insulating layer 303. Accordingly, a redundant description is omitted. As shown in FIG. 3A, the buffer oxide layer 351 is formed over underlying conductive patterns 305 and the first insulating layer 303 before an auxiliary layer 307 is formed. The buffer oxide layer 351 is formed to further improve the loss of the first insulating layer 303 occurring when a dry etch process for forming auxiliary patterns is performed. The buffer oxide layer 351 is removed through a cleaning process using a hydrofluoric (HF) acid solution or a buffered oxide etchant (BOE) after the auxiliary patterns are removed. Accordingly, as shown in FIG. 3B, metal wirings 315 according to the third embodiment of the present disclosure are formed with a stack structure of the buffer oxide layer 351 and the second insulating layer 311 interposed therebetween. In FIGS. 3A and 3B, reference numeral 301 identifies the semiconductor substrate.

Even in the third embodiment of the present disclosure, only an oxide layer remains as material insulating the metal wirings 315 from each other. Accordingly, the capacitance between the metal wirings 315 can be improved.

According to the present disclosure, although a nitride layer is not used, the stability of the process for forming the damascene patterns to define the regions in which the metal wirings will be formed can be improved. Accordingly, the capacitance between the metal wirings can be improved.

The present disclosure can reduce data error resulting from the interference between metal wirings because it can reduce the capacitance between the metal wirings.

In the case in which the method of forming the metal wirings according to the present disclosure is applied to a method of forming the bit lines of a NAND flash memory device, the sensing time can be reduced because the capacitance between the bit lines can be improved.

What is claimed is:

1. A method of forming metal wirings of a semiconductor device, the method comprising:
providing a semiconductor substrate comprising a number of underlying conductive patterns separated from each other with a first insulating layer interposed between the underlying conductive patterns;
forming auxiliary patterns over the underlying conductive patterns, respectively;
forming a second insulating layer over the first insulating layer to fill a space between the auxiliary patterns;
removing the auxiliary patterns to form damascene patterns through which the underlying conductive patterns are respectively exposed; and,
filling interiors of the damascene patterns with a metal material.

2. The method of claim 1, wherein forming auxiliary patterns comprises:
forming an auxiliary layer over the first insulating layer and the underlying conductive patterns; and,
etching the auxiliary layer to expose the first insulating layer, to form the auxiliary patterns.

3. The method of claim 2, wherein etching the auxiliary layer comprises dry etching.

4. The method of claim 1, wherein:
each of the first and second insulating layers comprises an oxide layer, and,
the auxiliary patterns comprise a silicon nitride (Si₃N₄) layer or a polysilicon layer.

5. The method of claim 4, wherein removing the auxiliary patterns comprises:
removing the silicon nitride (Si₃N₄) layer through a wet etch process using H₃PO₄, and,
removing the polysilicon layer using an etchant comprising a mixture of HF, HNO₃, and acetic acid.

6. The method of claim 1, wherein the second insulating layer comprises air gaps.

7. The method of claim 1 further comprising, before forming the auxiliary patterns, forming a buffer oxide layer over the underlying conductive patterns and the first insulating layer.

8. The method of claim 7, wherein removing the auxiliary patterns comprises removing the buffer oxide layer formed over the underlying conductive patterns after removing the auxiliary patterns.

9. The method of claim 2, wherein etching the auxiliary layer comprises dry etching the auxiliary layer with a material having a faster etch rate than a material used to etch the first insulating layer.
